(19) United States
(12) Patent Application Publication
(10) Pub. No.: US 2013/0112268 A1
(43) Pub. Date: May 9, 2013

(54) FILM CONTAINING AN ODOURLESS FLUORINATED ACRYLIC POLYMER FOR PHOTOVOLTAIC USE

(71) Applicants: Anthony Bonnet, Saint Laurent de Mure (FR); Francois Beaume, Saint Genis Laval (FR); Stephane Bizet, Barc (FR); Nicolas Devaux, Lyon (FR)

(72) Inventors: Anthony Bonnet, Saint Laurent de Mure (FR); Francois Beaume, Saint Genis Laval (FR); Stephane Bizet, Barc (FR); Nicolas Devaux, Lyon (FR)

(73) Assignee: Arkema France, Colombes (FR)

(21) Appl. No.: 13/522,037

(22) PCT Filed: Jan. 11, 2011
(86) PCT No.: PCT/FR2011/050044

§ 371 Date: Jan. 22, 2013

(30) Foreign Application Priority Data
Jan. 14, 2010 (FR) 1050226

(51) Int. Cl. C08K 3/22; H01L 31/048

(52) U.S. Cl. CPC C08K 3/22; H01L 31/0487
USPC 136/259; 428/220; 264/540; 524/432

(57) ABSTRACT

The present invention relates to a composition consisting of a fluoropolymer and a white inorganic filler, said composition being intended for the manufacture of monolayer films opaque to visible tight and to UV radiation, useable in particular in the field of photovoltaic cells. The polymeric composition consists of a fluoropolymer and zinc oxide (ZnO), said filler being present in said composition in a weight proportion of 20 to 40%, preferably 20 to 35%. The use of this filler serves on the one hand to avoid the addition of acrylic polymers to the fluoropolymer, and on the other hand, to use processing temperatures that are compatible with the manufacture of a monolayer film by extrusion blow moulding, that is, a temperature of about 220 to 260° C., thereby serving to prevent the degradation of the fluoropolymer.

The present invention relates to a composition consisting of a fluoropolymer and a white inorganic filler, said composition being intended for the manufacture of monolayer films opaque to visible light and to UV radiation, useable in particular in the field of photovoltaic cells.

In a photovoltaic cell, it is indispensable to ensure the protection of the components against environmental factors. Thus, the back of the cell must be protected by a polymer film to prevent its degradation by ultraviolet (UV) rays and the penetration of moisture. The protective film must have a body or dimensional thermal stability to avoid thermal expansion and, in particular, shrinkage during the assembly of the cells. Photovoltaic cells are assembled by bonding the various layers using a solvent-based adhesive, followed by lamination. The use of solvents in the adhesives can cause the penetration of said solvents into the film. The cells are assembled at high temperature (>130° C.) and optionally using a corona type surface oxidation treatment. When the protective film is based on fluoropolymer, this treatment may cause yellowing and deterioration of the mechanical properties thereof.

Furthermore, it is known how to use fluoropolymers in general and PVDF (polyvinylidene fluoride or vinylidene difluoride VDF) in particular to manufacture films for protecting objects and materials, due to their very good resistance to weather and UV radiation and to visible light, and also to chemicals. However, it is necessary for these films to have very good thermal resistance for outdoor applications subject to hostile climatic conditions (rain, cold, heat) or processing operations at high temperature (>130° C.). It is also necessary for the films to have good flexibility and good break strength in order to withstand the mechanical loads during their installation on the object or the material to be covered.

In general, to protect the polymer film against degradation by UV radiation, UV absorbers and/or inorganic fillers are incorporated therein. It is known that the addition of inorganic fillers such as TiO₂, SiO₂, CaO, MgO, CaCO₃, Al₂O₃ and many others to a fluoropolymer, such as a polymer or copolymer of vinylidene fluoride (PVDF), can cause rather violent deterioration, with the production of hydrogen fluoride (HF) when the mixing is carried out in the molten state at high temperature to disperse the filler. One method for using these fillers with PVDF, for example, consists in introducing these inorganic fillers using an acrylic masterbatch. For this purpose, the inorganic fillers are dispersed in a methyl methacrylate polymer or copolymer (PMMA), and said masterbatch is then mixed with molten PVDF. The presence of a PMMA can raise drawbacks such as a limitation of the high temperature dimensional stability of the film obtained, lower thermal resistance, a characteristic acrylic odour during the assembly of the cells, and lower UV stability in comparison with pure PVDF. Such a film comprising a tripartite fluoropolymer/acrylic polymer/inorganic filler composition is described for example in document WO 2009101343.

The present invention proposes to provide fluoropolymer-based compositions containing an inorganic filler for preparing films opaque to UV and visible radiation, while preserving very good dimensional stability properties at the temperatures used for the manufacture of a backsheet, and subsequently of a photovoltaic panel. The invention thereby serves to avoid the odour problems which may arise when an acrylic is used in the formulation of the film.

For this purpose, and according to a first aspect, the invention relates to a polymeric composition consisting of a fluoropolymer and zinc oxide (ZnO), said filler being present in said composition in a weight proportion of 20 to 40%, preferably 20 to 35%. The use of this filler serves on the one hand to avoid the addition of acrylic polymers to the fluoropolymer, and on the other hand, to use processing temperatures that are compatible with the manufacture of a monolayer film by extrusion blow moulding, that is, a temperature of about 220 to 260° C., thereby serving to prevent the degradation of the fluoropolymer.

Furthermore, the use of zinc oxide serves to obtain a film that is completely opaque to ultraviolet and visible radiation in a thickness of 10 to 40 μm, which can be used as a protective film of the PET used in the back portion of a photovoltaic panel to form an object called backsheet.

Advantageously, the composition of the invention contains no MMA homo- or copolymer.

According to a second aspect, the invention therefore relates to a monolayer film opaque to UV and visible radiation. Advantageously, the film of the invention has long term stability, as demonstrated by the damp heat test, at 85° C. and 85% humidity for 2000 h, and by the UV ageing test.

The invention also relates to the use of said film for manufacturing the backsheet of a photovoltaic panel. More particularly, the invention relates to a photovoltaic cell of which the backsheet is lined with a film as described above.

According to a further aspect, the invention relates to a method for preparing the abovementioned composition, said method comprising a step of incorporating said filler by melting in the fluoropolymer.

According to a further aspect, the invention relates to a method for manufacturing the abovementioned monolayer film by extrusion blow moulding at a temperature of 220 to 260° C.

The invention will now be described in detail.

According to a first aspect, the invention relates to a polymeric composition consisting of a fluoropolymer and a white inorganic filler, said filler being present in said composition in a weight proportion of 20 to 40%, preferably 20 to 35%, characterized in that said filler is zinc oxide (ZnO) and in that the fluoropolymer is a homopolymer or a copolymer of VDF and at least one other fluoromonomer.

The fluorocomonomer copolymerizable with VDF is selected for example from vinyl fluoride; trifluoroethylene (VF3); chlorotrifluoroethylene (CTFE); 1,2-difluoroethylene; tetrafluoroethylene (TFE); hexafluoropropylene (HFP); perfluoro(alkyl vinyl) ethers such as perfluoro(methyl vinyl)ether (PMVE), perfluoro(ethyl vinyl) ether (PEVE) and perfluoro(propyl vinyl) ether (PPVE); perfluoro(1,3-dioxole); perfluoro(2,2-dimethyl-1,3-dioxole) (PDD), and mixtures thereof. The fluorocomonomer is preferably selected from chlorotrifluoroethylene (CTFE), hexafluoropropylene (HFP), trifluoroethylene (VF3) and tetrafluoroethylene (TFE), and mixtures thereof. The comonomer is advantageously HFP because it copolymerizes well with VDF and serves to impart good thermomechanical properties. Preferably, the copolymer only comprises VDF and HFP.

Preferably, the fluoropolymer is a homopolymer of VDF (PVDF) or a copolymer of VDF such as VDF-HFP containing at least 50% by weight of VDF, advantageously at least 75% by weight of VDF and preferably at least 90% by weight of VDF. For example, mention can be made more particularly of the homopolymers or copolymers of VDF containing over 75% of VDF and the following HFP complement: Kynar® 710, Kynar® 720, Kynar® 740, Kynar Flex® 2850, Kynar Flex® 3120, sold by Arkema.

Advantageously, the homopolymer or a copolymer of VDF has a viscosity of 100 Pa.s to 3000 Pa.s, the viscosity being measured at 230° C., at a shear gradient of 100 s⁻¹, using a capillary rheometer. In fact, this type of polymer is highly appropriate for extrusion. Preferably, the polymer has a viscosity of 500 Pa.s to 2900 Pa.s, the viscosity being measured at 230° C., and a shear gradient of 100 s⁻¹, using a capillary rheometer. With regard to the white inorganic filler, it is zinc oxide (ZnO). It has an opacifying function in the UV/visible range, and plays the role of a solar filter so that the film prepared from the composition of the invention is an opaque film, mainly by diffusion/reflection of UV radiation, but also opaque to visible light. The inorganic filler content in the composition is between 20 and 40 wt %, advantageously between 20 and 35 wt % (inclusive).

According to one embodiment, the inventive composition consists of PVDF homopolymer and ZnO, and the weight content of the filler is 20 to 35%.

The inventive composition may be prepared by a method comprising a step of incorporation of the ZnO by melting in the fluoropolymer.

According to another aspect, the invention relates to a monolayer film manufactured from the composition described above. Said film is opaque to UV and visible radiation while preserving very good dimensional stability properties at the temperatures used for the manufacture of a backsheet, and subsequently of a photovoltaic panel.

The film of the invention has the following characteristics:
thickness between 10 and 40 μm, advantageously between 10 and 30 μm, preferably between 10 and 25 μm (inclusive);
density between 1.9 and 2.5 g/cm³ (inclusive);
basis weight between 19 and 125 g/m² (inclusive);
elongation at break (in %):
   machine direction: 200 to 300;
   crosswise direction: 180 to 270;
break stress (MPa):
   machine direction: 55 to 70;
   crosswise direction: 40 to 60;
dimensional change after placing in the oven for 30 min at 150° C. (in %):
   machine direction: 0.5 or less;
   crosswise direction: 0.5 or less.
      Said film is opaque to UV and visible radiation and has long-term stability as demonstrated by the damp heat test at 85° C. and 85% humidity for 2000 h, and by the UV ageing test.

Advantageously, the film of the invention does not have an acrylic odour.

The film of the invention is manufactured by extrusion blow moulding (blown film) at a temperature of 220 to 260° C. This technique consists in coextruding a thermoplastic polymer through an annular die, generally from the bottom upwards. The extrudate is simultaneously drawn longitudinally by a pulling device, usually in rolls, and inflated by a constant air volume imprisoned between the die, the pulling system and the film wall. The inflated film is generally cooled by an air blowing ring as it leaves the die.

Advantageously, the type of filler makes it possible to obtain the film by the extrusion blow moulding technique at temperatures of 220-260° C. without causing degradation of the fluoropolymer present in said composition. This serves to keep the particular properties of this polymer intact, that is, its very good resistance to weather, to UV radiation and visible light, and to chemicals.

According to a further aspect, the invention relates to the use of this film for manufacturing the backsheet of a photovoltaic panel. For this purpose, according to one embodiment, the film of the invention first undergoes a corona type surface treatment on both sides. It is then hot-laminated on each side of a PET sheet previously coated with adhesive. One side of the laminate thus obtained is then pressed on an EVA type film, and the other side thereof is bonded to a cleaned glass plate. This structure can be used as backsheet in a photovoltaic cell.

The film of the invention is opaque (low transmittance of visible light and UV radiation) and also offers protection against the penetration of oxygen. The structure preserves an attractive film appearance (no yellowing over time) and excellent fire resistance.

The fluoropolymer-based film of the invention has good thermal resistance (low body shrinkage when subjected to high temperatures) and also excellent resistance to the solvents present in the glues and adhesives used for the construction of the photovoltaic cells, and more particularly of the backsheet of the cells. This structure is therefore perfectly appropriate for protecting the backsheet of the photovoltaic cells.

The present invention will be better understood by considering the exemplary embodiments that follow.

### Measurement of Mechanical Properties

The elongation at break and break stress in the two film directions were measured according to standard EN 06074-2.

### Dimensional Stability Test

The film shrinkage is measured according to standard ISO 11501. A square piece of film. measuring 20 cm×20 cm is placed in a ventilated oven at 150° C. for 30 min. The dimensions are then measured again. The shrinkage is determined from the change in each of the dimensions, related to the initial dimension.

### UV Ageing Test

The accelerated UV ageing test is carried out in QUV, by applying the following conditions to the sample: 8 hours of QUV B 313 (UV-B lamps at 313 nm) at 60° C., 0.89 W/m²/nm then 4 hours at 45° C., with water condensation on the sample. This test is performed for 5000 h.

### Damp Heat Test

The test is performed in a climatic chamber where a temperature of 85° C. and 85% humidity are maintained. After 2000 h, the samples are taken and analyzed.

### EXAMPLE 1 (According to the Invention)

A mixture was prepared in a BUSS PR 461) type extrusion machine at 230° C. and 200 rpm at a rate of 40 kg/h. Said mixture comprised 20% Pharma A grade ZnO from Umicore having a specific gravity of 5.6 and a refractive index of 2 and 80% Kynar 740 from Arkema having MFI=2.3 under 5 kg at 230° C. The product obtained was in the form of white and opaque granules. A thermogravimetric and dynamic analysis at 20° C./minute in air of the product thus prepared revealed no significant weight loss (>0.1%) before 350° C. The same analysis performed in air at 250° C. for one hour in isothermal conditions revealed no weight loss.

The product thus obtained was then extruded in the form of a 20 μm film on a Kiefel type extrusion machine. The film was produced at a rate of 20 m/minute and had a density of 2.06 g/cm³ and a basis weight of 41.2 g/m². The measurement of the mechanical properties gave an elongation at break of 270% in the machine direction and an elongation of 235% in the crosswise direction. The break stress in the machine direction was 63.5 MPa and 51 MPa in the crosswise direction. A dimensional stability test was performed at 150° C. for 30 minutes. A 20 cm×2.0 cm film was placed in a ventilated oven. The dimensions of the film were measured before and after the passage in the oven, and only a slight contraction of the film of 0.5% was observed in the crosswise direction, with no dimensional change measured in the machine direction or at least one lower than 0.25%.

Said film was then hot-laminated at 100° C. on each side of a PET sheet on which a two-component adhesive from Bostik, a mixture of RBIS EPS 877 and Boscodur 1621, had previously been applied. The film was previously corona treated on both sides. The adhesion was measured 2 weeks after this lamination step and a value of 12 N/cm was obtained. A thermal stability test was again performed on the laminate at 150° C. for 30 minutes applying the same conditions as on the free film. No change was observed in the film and also no delamination.

One side of the laminate thus obtained was then pressed directly on Ultra Fast Cure EVA from Etimex, the other side of the EVA film being bonded to a glass plate previously degreased with ethanol and with MEK (methyl ethyl ketone). The bonding and cross-linking were carried out simultaneously at a temperature of 150° C. for 10 minutes. An adhesion higher than 100 N/cm was obtained when a 90° peeling was carried out.

The structure was then tested for 2000 h by a damp heat test at 85° C. and 85% humidity, without any change in appearance and no delamination of the layers.

A QUVB UV ageing test was performed using a cycling of 8 hours in QUVB 313 at 60° C. with an energy of 0.89 W/m²/nm and 4 hours in condensation at 45° C. After 5000 h of cycling, no yellowing, no deterioration and no delamination between the layers was observed.

### EXAMPLE 2 (According to the Invention)

A mixture was prepared in a BUSS PR 46D type extrusion machine at 230° C. and 200 rpm at a rate of 40 kg/h. Said mixture comprised 30% Pharma A grade ZnO from Umicore having a specific gravity of 5.6 and a refractive index of 2 and 70% Kynar 740 from Arkema having MFI=9 under 12.5 kg at 230° C. The product obtained was in the form of white and opaque granules. A thermogravimetric and dynamic analysis at 20° C./minute in air of the product thus prepared revealed no significant weight loss (>0.1%) before 350° C. The same analysis performed in air at 250° C. for one hour in isothermal conditions revealed no weight loss.

The product thus obtained was then extruded in the form of a 20 μm film on a Kiefel type extrusion machine. The film was produced at a rate of 20 m/minute and had a density of 2.24 g/cm³ and a basis weight of 44.8 g/m². The measurement of the mechanical properties gave an elongation at break of 217% in the machine direction and an elongation of 189% in the crosswise direction. The break stress in the machine direction was 57 MPa and 45 MPa in the crosswise direction. A dimensional stability test was performed at 150° C. for 30 minutes. A 20 cm×20 cm film was placed in a ventilated oven. The dimensions of the film were measured before and after the passage in the oven, and only a slight contraction of the film of 0.25% was observed in the crosswise direction, with no dimensional change measured in the machine direction or at least one lower than 0.25%.

Said film was then hot-laminated at 100° C. on each side of a PET sheet on which a two-component adhesive from Bostik, a mixture of HBTS EPS 877 and Boscodur 1621, had previously been applied. The film was previously corona treated on both sides. The adhesion was measured 2 weeks after this lamination step and a value of 12 N/cm was obtained. A thermal stability test was again performed on the laminate at 150° C. for 30 minutes applying the same conditions as on the free film. No change was observed in the film and also no delamination.

One side of the laminate thus obtained was then pressed directly on Ultra Fast Cure EVA from Etimex, the other side of the EVA film being bonded to a glass plate previously degreased with ethanol and with MEK. The bonding and cross-linking were carried out simultaneously at a temperature of 150° C. for 10 minutes. An adhesion higher than 100 N/cm was obtained when a 90° peeling was carried out.

The structure was then tested for 2000 h by a damp heat test at 85° C. and 85% humidity, without any change in appearance and no delamination of the layers.

A QUVB UV ageing test was performed using a cycling of 8 hours in QUVB 313 at 60° C. with an energy of 0.89 W/m²/nm and 4 hours in condensation at 45° C. After 5000 h of cycling, no yellowing, no deterioration and no delamination between the layers was observed.

### EXAMPLE 3 (According to the Invention)

A mixture was prepared in a BUSS PR 46D type extrusion machine at 230° C. and 200 rpm at a rate of 40 kg/h. Said mixture comprised 35% Pharma A grade ZnO from

Umicore having a specific gravity of 5.6 and a refractive index of 2 and 65% Kynar 740 from Arkema having MEI=9 under 12.5 kg at 230° C. The product obtained was in the form of white and opaque granules. A thermogravimetric and dynamic analysis at 20° C./minute in air of the product thus prepared revealed no significant weight toss (>0.1%) before 350° C. The same analysis performed in air at 250° C. for one hour in isothermal conditions revealed no weight loss.

The product thus obtained was then extruded in the form of a 20 μm film on a Kiefel type extrusion machine. The film was produced at a rate of 20 m/minute and had a density of 2.34 g/cm³ and a basis weight of 46.8 g/m². The measurement of the mechanical properties gave an elongation at break of 200% in the machine direction and an elongation of 190% in the crosswise direction. The break stress in the machine direction was 59 MPa and 45 MPa in the crosswise direction. A dimensional stability test was performed at 150° C. for 30 minutes. A 20 cm×20 cm film was placed in a ventilated oven. The dimensions of the film were measured before and after the passage in the oven, and only a slight contraction of the film of 0.25% was observed in the crosswise direction, with no dimensional change measured in the machine direction or at least one lower than 0.25%.

Said film was then hot-laminated at 100° C. on each side of a PET sheet on which a two-component adhesive from Bostik, a mixture of HBTS EPS 877 and Boscodur 1621, had previously been applied. The film was previously corona treated on both sides. The adhesion was measured 2 weeks after this lamination step and a value of 11 N/cm was obtained. A thermal stability test was again performed on the laminate at 150° C. for 30 minutes applying the same conditions as on the free film. No change was observed in the film and also no delamination.

One side of the laminate thus obtained was then pressed directly on Ultra Fast Cure EVA from Etimex, the other side of the EVA film being bonded to a glass plate previously degreased with ethanol and with MEK. The bonding and cross-linking were carried out simultaneously at a temperature of 150° C. for 10 minutes. An adhesion higher than 100 N/cm was obtained when a 90° peeling was carried out.

The structure was then tested for 2000 h by a damp heat test at 85° C. and 85% humidity, without any change in appearance and no delamination of the layers.

A QUVB UV ageing test was performed using a cycling of 8 hours in QUVB 313 at 60° C. with an energy of 0.89 W/m²/nm and 4 hours in condensation at 45° C. After 5000 h of cycling, no yellowing, no deterioration and no delamination between the layers was observed.

### EXAMPLE 4 (According to the Invention)

A mixture was prepared in a BUSS PR 461) type extrusion machine at 230° C. and 200 rpm at a rate of 40 kg/h. Said mixture comprised 40% Pharma A grade ZnO from Umicore having a specific gravity of 5.6 and a refractive index of 2 and 60% Kynar 740 from Arkema having MFI=9 under 12.5 kg at 230° C. The product obtained was in the form of white and opaque granules. A thermogravimetric and dynamic analysis at 20° C./minute in air of the product thus prepared revealed no significant weight loss (>0.1%) before 350° C. The same analysis performed in air at 250° C. for one hour in isothermal conditions revealed no weight loss.

The product thus obtained was then extruded in the form of a 20 μm film on a Kiefel type extrusion machine. The film was produced at a rate of 20 m/minute and had a density of 2.45 g/cm³ and a basis weight of 49 g/m². The measurement of the mechanical properties gave an elongation at break of 190% in the machine direction and an elongation of 170% in the crosswise direction. The break stress in the machine direction was 59 MPa and 43 MPa in the crosswise direction. A dimensional stability test was performed at 150° C. for 30 minutes. A 20 cm×20 cm film was placed in a ventilated oven. The dimensions of the film were measured before and after the passage in the oven, and only a slight contraction of the film of 0.25% was observed in the crosswise direction, with no dimensional change measured in the machine direction or at least one lower than 0.25%.

Said film was then hot-laminated at 100° C. on each side of a PET sheet on which a two-component adhesive from Bostik, a mixture of HBTS EPS 877 and Boscodur 1621, had previously been applied. The film was previously corona treated on both sides. The adhesion was measured 2 weeks after this lamination step and a value of 11 N/cm was obtained. A thermal stability test was again performed on the laminate at 150° C. for 30 minutes applying the same conditions as on the free film. No change was observed in the film and also no delamination.

One side of the laminate thus obtained was then pressed directly on Ultra Fast Cure EVA from Etimex, the other side of the EVA film being bonded to a glass plate previously degreased with ethanol and with MEK. The bonding and cross-linking were carried out simultaneously at a temperature of 150° C. for 10 minutes. An adhesion higher than 100 N/cm was obtained when a 90° peeling was carried out.

The structure was then tested for 2000 h by a damp heat test at 85° C. and 85% humidity, without any change in appearance and no delamination of the layers.

A QUVB UV ageing test was performed using a cycling of 8 hours in QUVB 313 at 60° C. with an energy of 0.89 W/m²/nm and 4 hours in condensation at 45° C. After 5000 h of cycling, no yellowing, no deterioration and no delamination between the layers was observed.

### EXAMPLE 5 (Comparative)

A mixture was prepared in a BUSS PR 46D type extrusion machine at 230° C. and 200 rpm at a rate of 40 kg/h. Said mixture comprised 15% TiO₂ having a specific gravity of 4.2 and a refractive index of 2.7, 65% Kynar 740 from Arkema having MFI=2.3 under 5 kg at 230° C., and 20% PMMA V825 T from Altuglas. The product obtained was in the form of white and opaque granules. A thermogravimetric and dynamic analysis at 20° C./minute in air of the product thus prepared revealed no significant weight loss (>0.1%) before 315° C. The same analysis performed in air at 250° C. for one hour in isothermal conditions revealed no weight loss. The product thus obtained was then extruded in the form of a 20 μm film on a Kiefel type extrusion machine. The film was produced at a rate of 20 m/minute and had a density of 1.7 g/cm³ and a basis weight of 34 g/m². The measurement of the mechanical properties gave an elongation at break of 250% in the machine direction and an elongation of 249% in the crosswise direction. The break stress in the machine direction was 64 MPa and 50 MPa in the crosswise direction. A dimensional stability test was performed at 150° C. for 30 minutes. A 20 cm×20 cm film was placed in a ventilated oven. The dimensions of the film were measured before and after the passage in the oven, and only a slight contraction of the film of 0.25% was observed in the crosswise direction, with no dimensional change measured in the machine direction or at least one lower than 0.25%.

Said film was then hot-laminated at 100° C. on each side of a PET sheet on which a two-component adhesive from Bostik, a mixture of HBTS EPS 877 and Boscodur 1621, had previously been applied. The film was previously corona treated on both sides. The adhesion was measured 2 weeks after this lamination step and a value of 12 N/cm was obtained. A thermal stability test was again performed on the laminate at 150° C. for 30 minutes applying the same conditions as on the free film. No change was observed in the film and also no delamination. An odour of acrylic was detected. An atmosphere analysis revealed a methyl methacrylate content of 0.7 ppm in the atmosphere. The odour was detected because the olfactory detection limit of methyl methacrylate is 0.05 ppm.

One side of the laminate thus obtained was then pressed directly on Ultra Fast Cure EVA from Etimex, the other side of the EVA film being bonded to a glass plate previously degreased with ethanol and with MEK. The bonding and cross-linking were carried out simultaneously at a temperature of 150° C. for 10 minutes. An adhesion higher than 100 N/cm was obtained when a 90° peeling was carried out. However, an odour of acrylic was observed near the sample. An atmosphere analysis revealed a methyl methacrylate content of 0.5 ppm in the atmosphere. The odour was detected because the olfactory detection limit of methyl methacrylate is 0.05 ppm.

The structure was then tested for 2000 h by a damp heat test at 85° C. and 85% humidity. A slight yellowing was observed, but without any delamination.

A QUVB UV ageing test was performed using a cycling of 8 hours in QUVB 313 at 60° C. with an energy of 0.89 W/m²/nm and 4 hours in condensation at 45° C. After 5000 h of cycling, no yellowing, no deterioration and no delamination between the layers was observed.

1. Polymeric composition consisting of a fluoropolymer and zinc oxide (ZnO), the ZnO being present in said composition in a weight proportion of 20 to 40%, said fluoropolymer being a homopolymer of vinylidene difluoride, or a copolymer of vinylidene difluoride and at least one other fluoromonomer.

2. Composition according to claim 1, in which said fluoropolymer is polyvinylidene fluoride (PVDF).

3. Composition according to claim 2, consisting of about 80% PVDF and about 20% ZnO.

4. Composition according to claim 2, consisting of about 70% PVDF and about 30% ZnO.

5. Composition according to claim 2, consisting of about 65% PVDF and about 35% ZnO.

6. Composition according to claim 2, consisting of about 60% PVDF and about 40% ZnO.

7. Monolayer film consisting of the composition according to claim 1, characterized in that it is opaque to UV and visible radiation and in that it has long-term stability, as demonstrated by the damp heat test at 85° C. and 85% humidity for 2000 h and by the QUV ageing test.

8. Film according to claim 7, having a thickness of 10 to 40 μm.

9. Photovoltaic panel in which the backsheet comprises a film according to claim 7.

10. (canceled)

11. (canceled)

12. Method for manufacturing the monolayer film according to claim 7, by extrusion blow moulding at a temperature of 220 to 260° C.

13. Composition according to claim 1, wherein said ZnO is present in said composition in a weight proportion of 20 to 35%.

14. Film according to claim 8, having a thickness of 10 to 30 μm.

15. Film according to claim 14, having a thickness of 10 to 25 μm.
